(19) United States
(12) Patent Application Publication
(10) Pub. No.: US 2008/0073205 A1
(43) Pub. Date: Mar. 27, 2008

(54) Integrated photovoltaic-electrolysis cell

(75) Inventors: Mahabala Adiga, Toledo, OH (US); Xunming Deng, Sylvania, OH (US); Aarohi Vijh, Sylvania, OH (US); Liwei Xu, Sylvania, OH (US)

Correspondence Address: MACMILLAN SOBANSKI & TODD, LLC, ONE MARITIME PLAZA FIFTH FLOOR, 720 WATER STREET, TOLEDO, OH, 43604-1619, US

(73) Assignees: University of Toledo, Toledo, OH (US); MWOE. Inc., Toledo, OH (US)

(21) Appl. No.: 11/974,191

(22) Filed: Oct. 11, 2007

Related U.S. Application Data
(63) Continuation of application No. PCT/US2006/013222, filed on Apr. 10, 2006.
(60) Provisional application No. 60/670,177, filed on Apr. 11, 2005.

(51) Int. Cl. C25B 9/00; H01L 31/052

(52) U.S. Cl. 204/263; 204/275.1

(57) ABSTRACT

A photovoltaic electrolysis (IPE) cell has a photovoltaic component and an electrolysis component which integrated, through an interconnect design, into a single unit.

### CROSS-REFERENCE TO RELATED APPLICATIONS

This application claims the benefit of U.S. Provisional Application No. 60/670,177 filed Apr. 11, 2005, and PCT/US2006/013222 filed Apr. 10, 2006, the disclosures of which are incorporated herein by reference.

### TECHNICAL FIELD

The instant invention relates generally to the generation of hydrogen and oxygen from water through a photo-electrolysis process and more particularly to the generation of hydrogen using solar radiation.

This invention was made with support under: 1) DOE grant “Development of Improved Materials for Integrated Photovoltaic-Electrolysis Hydrogen Generation Systems”, awarded to Midwest Optoelectronics LLC under subcontract under subcontract EFC-H1-16-2A through Edison Materials and Technology Center, Inc., 2) NSF-Partnership For Innovation Program awarded to the University of Toledo and sub-awarded to Midwest Optoelectronics, LLC; 3) AFRL-WPAFB Grant “Photovoltaic Hydrogen for Portable, On-Demand Power” awarded to the University of Toledo under subcontract 03-S530-0011-01C1 under the primary contract F33615-02-D-2299 through the Universal Technology Corporation; 4) Midwest Optoelectronics's Internal research and development finds; and, 5) University of Toledo's internal research and development funds. The government has certain rights in this invention.

### BACKGROUND OF THE INVENTION

Future transportation is widely believed to be based on a hydrogen economy. Using fuel cells, cars and trucks will no longer burn petroleum and will no longer emit CO₂ on the streets since they will use hydrogen as the fuel and the only byproduct is water. However, the reforming process, the main process that is used in today's hydrogen production, still uses petroleum based products as the raw material and still emits large amounts of CO₂. To reduce our society's reliance on petroleum based products and to avoid the emission of CO₂ that causes global warming, a renewable method of generating hydrogen must be developed.

An electrolysis process using only sunlight and water is considered to be one choice for hydrogen generation. Such hydrogen fuel is ideal for proton exchange membrane fuel cell (PEMFC) applications since it contains extremely low concentrations of undesirable carbon monoxide, which is poisonous to platinum catalysts in PEM fuel cells. However, indirect photo-electrolysis, in which the photovoltaic cells and electrodes are separated and connected electrically using external wires, is not cost-effective. An integrated photoelectrochemical cell (PEC) offers the potential to generate hydrogen renewably and cost effectively.

Several prior inventions and publications have disclosed designs for photoelectrochemical cells: U.S. Pat. No. 4,090,933 (Nozik), U.S. Pat. No. 4,144,147 (Jarrett et al.), U.S. Pat. No. 4,236,984 (Grantham), U.S. Pat. No. 4,310,405 (Heller), U.S. Pat. No. 4,544,470 (Hetrick), U.S. Pat. No. 4,628,013 (Figard et al.), U.S. Pat. No. 4,650,554 (Gordon), U.S. Pat. No. 4,656,103 (Reichman et al.), U.S. Pat. No. 5,019,227 (White et al.), U.S. Pat. No. 6,361,660 (Goldstein), U.S. Pat. No. 6,471,850 (Shiepe et al.), U.S. Pat. No. 6,471,834 (Roe et al.).

Design considerations for a hybrid amorphous silicon/photoelectrochemical multi-junction cell for hydrogen production, Miller, E. L.; Rocheleau, R. E., Deng, X. M., Int. J. Hydrogen Energy, 28(6), 2003, 615-623.

Photo-electrochemical hydrogen generation from water using solar energy, Material-related aspects, Bak, T.; Nowotny, J.; Rekas, M.; Sorrell, C. C., Int. J. Hydrogen Energy, 27 (10), 2002, 991-1022.

Photovoltaic water electrolysis using the sputter-deposited a-Si/c-Si solar cells, Ohmori, T.; Go, H.; Yamaguchi, N.; Nakayama, A.; Mametsuka, H.; Suzuki, E., Int. J. Hydrogen Energy 26 (7), 2001, 661-664.

Modeling of advanced alkaline electrolyzers: a system simulation approach, Oystein Ulleberg, Int. J. Hydrogen Energy, 28(1), 2003, 21-33.

Hybrid PV/fuel cell system design and simulation, Th. F. Ell-Shatter, M. N. Eskandar, M. T. El-Hagry, Renewable Energy 27(2002) 479-485.

Evaluation of a 5 kWₚ photovoltaic hydrogen production and storage installation for a residential home in Switzerland, Hollmuller, Pierre; Joubert, Jean-Marc; Lachal, Bernard; Yvon, Klaus, Int. J. Hydrogen Energy, 25 (2) 2000, 97-109.

The German-Saudi HYSOLAR program, Abaoud, Hassan; Steeb, Hartmut, Int. J. Hydrogen Energy, 23(6) 1998, 445-449.

Ten years of solar hydrogen demonstration project at Neunburg vorm Wald, Germany, Szyszka, A., Int. J Hydrogen Energy, 23(10), 1998, 849-860.

Solar photoproduction of hydrogen: a review, J. R. Bolton; Solar Energy, 57, 1996, 37.

Photoelectrochemical decomposition of water utilizing monolithic tandem cells; S. S. Kocha, D. Montgomery, M. W. Peterson, J. A. Turner Solar Energy Materials & Solar Cells, 52, 1998, 389.

Efficient solar generation of hydrogen fuel—a fundamental analysis; S. Licht, Electrochemistry Communications 4, 2002, 790.

Studies on PV assisted PEC solar cells for hydrogen production through photoelectrolysis of water; P. K. Shukla, R. K. Karn, A. K. Singh, O. N. Srivastava, Int. J. Hydrogen Energy, 27, 2002, 135.

Photoelectrochemical decomposition of water using modified monolithic tandem cells; X. Gao, S. Kocha, A. Frank, J. A. Turner, Int. J. Hydrogen Energy, 24, 1999, 319.

Photoelectrochemical production of hydrogen: Engineering loss analysis; R. E. Rocheleau and E. L. Miller, Int. J. Hydrogen Energy, 22, 1997, 771.

Most photoelectrochemical cells used for generation of hydrogen are based on photocatalysts and semiconducting materials which have a common photocatalyst and electrolyte configuration. The main drawbacks of these systems include the limitation of spectral response in the solar energy spectrum, the lack of established long term stability, and in some cases, photo-corrosion of the cell components. Although newer doped photo-catalysts based on TiO₂ exhibit some promise, only long term establishment of stability and reliability will prove its capability as a useful solution.

The prior art devices and methods described and disclosed in these above mentioned patents and publications also have at least one of the following drawbacks:

the photovoltaic cell does not generate sufficient voltage to split water;

the photovoltaic cell needs an external electrical bias for the electrolysis;

the photovoltaic device will not survive for extended use in the electrolyte due to inappropriate protection;

the photovoltaic device cannot be fabricated using low-cost methods; and/or,

the photovoltaic device does not have potential for high conversion efficiency.

Also, in the past, photovoltaic devices had separate electrolyzers and photovoltaic panels which were kept separate using an interface called MPPT (maximum power point tracker), which is a DC-DC converter positioned between the photovoltaic panel and the electrolyzer.

Currently, the state-of-the-art integrated photovoltaic electrolyzers use photovoltaic cells and the DC-DC converters (MPPT's) that track the locus of maximum power points of the Current-Voltage characteristics of the photovoltaic panels in order to keep the load along the maximum power points and to keep electrolyzer separate from the solar cells. The DC-DC converters, most of which are microprocessor controlled load matching devices, have a maximum efficiency of 92% at the rated load for MOSFET based systems. This maximum efficiency is observed only at the maximum rated load. At lower load ratings, the efficiency drops considerably. This results in lower efficiencies at 0.1 sun to about 0.6 sun, and resulting in lower load matching efficiencies between the photovoltaic panel and the electrolyzer from sunrise to about 10 AM and again from about 2 PM to sunset. Also, there is power dissipation loss in the system. This loss is higher for higher current passing through the system.

Three patent applications were recently filed by certain of the inventors herein of this invention, PCT/US03/37733 filed Nov. 24, 2003 (claiming priority from Ser. No. 60/428,841 filed Nov. 25, 2002) and PCT/US03/37543 filed Nov. 24, 2003 (claiming priority from Ser. No. 60/429,753 filed Nov. 25, 2002). In these earlier inventions, multiple-junction thin-film solar cells are used as photoelectrodes for photoelectrochemical production of hydrogen. The photoelectrodes are not deposited on insulation and transparent substrates or superstrates. In these photoelectrodes, the front electrical contact, (front electrode, front contact) are not sandwiched between the insulating substrate and the semiconductor layers.

### SUMMARY OF THE INVENTION

This invention relates to the field of art of solar photovoltaic cells for conversion of sunlight into hydrogen generation by electrolysis.

An integrated photovoltaic electrolysis (IPE) cell has a photovoltaic component and an electrolysis component which are integrated, through an interconnect design, into a single unit.

The photovoltaic component is comprised of: a superstrate or a substrate; a transparent conducting front electrode; one or more of photovoltaic junction(s); and, an electrically conductive back electrode.

The electrolysis component is comprised of: an electrolyte and an enclosure that confines the electrolyte. The electrolysis component includes a reduction compartment for hydrogen generation, and an oxidation compartment for oxygen generation. A cathode is electrically connected to the negative electrode of the photovoltaic component. Such cathode is either made of or coated with a stable hydrogen generation catalyst material that has low hydrogen evolution overpotential and is electrochemically stable under reduction environment. An anode is electrically connected to the positive electrode of the photovoltaic component. Such anode is either made of or coated with a stable oxygen generation catalyst material that has low oxygen evolution overpotential and is electrochemically stable under oxidation environment.

The electrolysis component further includes an electrolyte inlet for each or both of the reduction and oxidation compartments; an outlet for electrolyte and hydrogen in the reduction compartment; and, an outlet for electrolyte and oxygen in the oxidation compartment.

In certain embodiments, the photovoltaic component is a superstrate-type thin-film photovoltaic cell deposited on a glass superstrate. The photovoltaic component can be subdivided into a multiple of subcells; with appropriate dimensions such that the electrical loss in the transparent and conducting front contact is minimal.

In certain other embodiments, the photovoltaic component is a substrate-type thin-film photovoltaic cell which is deposited on a conducting substrate and has one or more photovoltaic junctions, so that the photovoltage is sufficient to drive electrolysis.

The substrate-type thin film photovoltaic cell can comprise electrical grids applied on top of the transparent conducting front electrode; wherein spacing of the grids is such that the electrical loss in the transparent and conducting front electrode is minimal. The electrical grids are electrically connected together and to one electrode of the electrolysis component. The conducting substrate is electrically connected to the other electrode of the electrolysis component, or itself is the other electrode.

Various objects and advantages of this invention will become apparent to those skilled in the art from the following detailed description of the preferred embodiment, when read in light of the accompanying drawings.

### BRIEF DESCRIPTION OF THE DRAWINGS

FIG. 1 is a schematic perspective illustration of a substrate-type integrated photovoltaic electrolysis (IPE) cell.

FIG. 2a is a schematic perspective illustration, partially in phantom, of a photovoltaic component and an electrolysis component on a superstrate-type IPE cell.

FIG. 2b is a schematic side elevational illustration of the photovoltaic component in an superstrate-type IPE cell shown in FIG. 2a.

FIG. 2c is a schematic perspective illustration, partially in phantom, of the electrolysis component shown in FIG. 2a.

FIG. 2d is a schematic bottom illustration of a superstrate type IPE cell shown in FIG. 2a.

### DETAILED DESCRIPTION OF THE PREFERRED EMBODIMENT

The integrated, or unitary, photovoltaic electrolysis (IPE) cell described herein allows photo-generated voltage from photovoltaic cells to be directly applied to anodes and cathodes that are in contact with an electrolyte. This close proximity avoids any voltage drop. The integrated photovoltaic electrolysis (IPE) cell allows, in any situation where the photo-generated voltage is not sufficient to split water, the voltage from neighboring subcells being stacked in an integrated and cost-effective manner, to drive electrolysis of water. The integrated photovoltaic electrolysis (IPE) cell also allows hydrogen to be generated efficiently over extended periods of time. Further, the integrated photovoltaic electrolysis (IPE) cell allows for the fabrication of such devices at low cost.

The integrated photovoltaic electrolysis (IPE) cell described herein is not based on water splitting using photo-catalytic semiconductor for photoelectrochemical cells.

The integrated photovoltaic electrolysis (IPE) cell provides a method for the photovoltaic electrochemical production of hydrogen (and oxygen) by incorporating, in a unitary manner either a substrate type or a superstrate type photovoltaic component with an electrolysis component.

The integrated photovoltaic electrolysis (IPE) cell minimizes the electrical power losses and hence improves the solar-to-hydrogen conversion efficiency.

In the substrate configuration, the required electrical potential is generated by a multijunction photovoltaic cell with an open circuit voltage in excess of approximately 2 V. The substrate of the photovoltaic cell itself functions as an electrode for electrolysis.

In the superstrate configuration, the required electric potential for electrolysis is generated by a multijunction photovoltaic cell with a high open-circuit voltage, or by combining the potentials of two or more lower open-circuit voltage cells by the use of scribes. The current produced by the photovoltaic cell is collected through a scribing arrangement and, via connection bus bars, is fed to a load matched electrolyzer housed in the same enclosure as the photovoltaic cell.

The integrated photovoltaic electrolysis (IPE) cell eliminates the need for the use of the DC-DC converter and thus eliminates the power dissipation losses normally associated with its use.

Also, the improved integrated photovoltaic electrolysis (IPE) cell maximizes the load matching efficiency. The integrated photovoltaic electrolysis (IPE) cell operates nearer the maximum power points of the Current-Voltage and Power-Voltage characteristics of the photovoltaic cell than prior devices.

The integrated photovoltaic electrolysis (IPE) cell has two different configurations, each which achieves the desired results without using the DC-DC converter interface. The first configuration uses the surface of a photovoltaic cell itself as one of the electrodes. Electrolytes flow adjacent to the cell, in what is called herein a substrate-type configuration of the integrated photovoltaic electrolysis (IPE) cell. The second configuration uses etchings, bifurcations and/or interconnections on the photovoltaic cell itself to provide an open circuit voltage from 2 to 2.8 volts.

In certain embodiments, the integrated photovoltaic electrolysis (IPE) cell is designed to match the load for tandem photovoltaic cells so that the integrated photovoltaic electrolysis (IPE) cell is operated near the maximum power points of the current-voltage characteristics of the photovoltaic cells. These configurations not only eliminate the need for DC-DC converters, but also eliminate the potential drop which occurred in the connecting cables which ran from the photovoltaic cells to the electrolyzer units in the prior electrolyzer systems.

In the integrated photovoltaic electrolysis (IPE) cell, instead of carrying the power to the electrolyzer units, the hydrogen is generated right next to the cells, and the generated hydrogen is transported to a desired point of collection. This hydrogen generation substantially reduces the I²R power losses, where I is the current and R is the resistance of the connecting cable.

Referring now to the Figures, the integrated photovoltaic electrolysis (IPE) cell 3 includes photovoltaic components 1 and electrolysis components 2 which are closely integrated in a manner that minimizes power losses in interconnections.

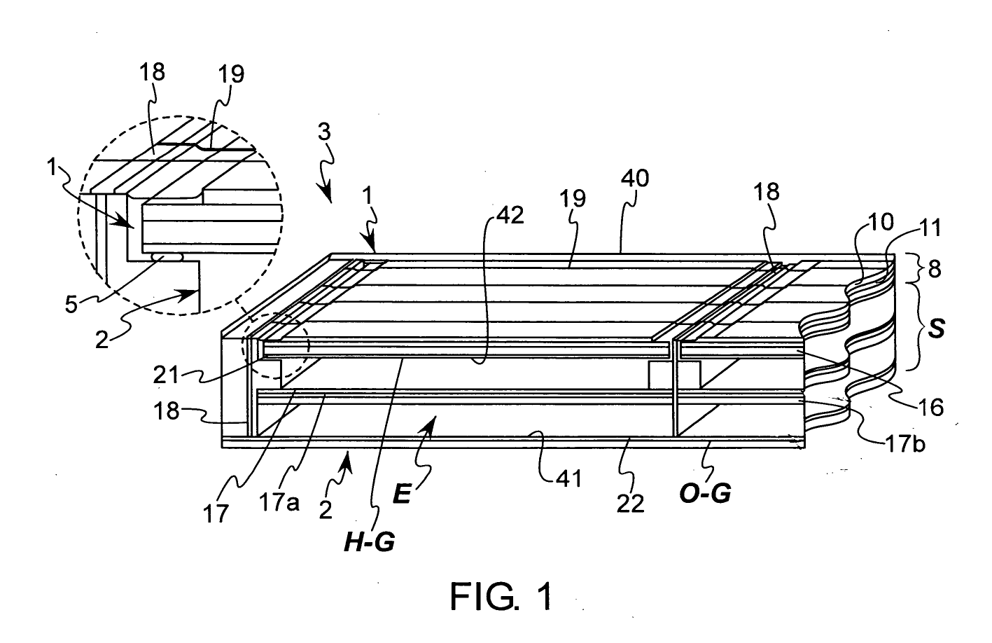

Referring first to FIGS. 1, a photovoltaic cell 8 comprises a substrate 16, photovoltaic layers 11 and transparent conducting front electrode 10. The photovoltaic cell 8 is deposited on a back contact plate 16, such as a stainless steel substrate. In certain embodiments, the photovoltaic cell 8 has p-i-n junctions composed of semiconducting-layers of hydrogenated amorphous silicon, amorphous germanium or their alloys, transparent conducting layers of zinc oxide and/or indium-tin oxide, and metallic reflector layers of silver or aluminum. The stainless steel back plate 16 may itself be coated with a hydrogen evolution (H-E) catalyst for electrolysis; i.e., thus forming a cathode 21. In other embodiments, the photovoltaic cell 8 may be bonded to a second plate (not shown) which has the same or similar size and is coated with the H-E catalyst such that the second plate acts as the first electrode, or cathode. In still other embodiments, the conductive substrate could itself be a catalyst.

An anode, or second electrode, 22 is also employed. The anode 22 is separated from the first electrode 21 by a membrane 17 that allows flow of ions and molecules, but not of gas bubbles. In certain embodiments, the membrane can be secured with a porous support 17a and/or a plastic mesh 17b.

The anode 22 is electrically connected via interconnections 18 to one or more grids 19 on a front surface of the photovoltaic cell 8. These electrical connections 18 are made sufficiently numerous so that the effective connection length and the corresponding electrical power loss is minimized. In this embodiment, the electrodes 21 and 22 have areas of the same order as that of the photovoltaic cell 8; therefore, the current density at the electrodes 21 and 22 is of the same order as the photovoltaic cell current density (5-10 mA/cm²). It is to be understood that those familiar with this area of knowledge will recognize that this current density, especially in combination with an effective catalyst, is sufficiently low as to minimize problems of electrode overpotential.

The anode 22 is coated with an effective catalyst (O-G) for oxygen generation while, as stated above, the cathode 21 is coated with an effective catalyst (H-G) for hydrogen generation. In certain embodiments, a space S between the electrodes 21 and 22 is approximately 2-3 cm. The space S between the electrodes and the membrane 17 is filled with an electrolyte E; for example, a 30% aqueous solution of KOH. The photovoltaic cell 8, the oxygen evolution anode 22, the membrane 17, and the hydrogen evolution cathode 21 can be encapsulated by suitable material such as EVA so that an enclosure 40 is formed.

In the embodiment shown in FIG. 1, the enclosure 40 has at least two electrolyte inlets, generally shown as 41 and 42, one on each side of the membrane, and one or more outlets (not shown), on each side of the membrane 17 for the exiting of the electrolyte and evolved gases.

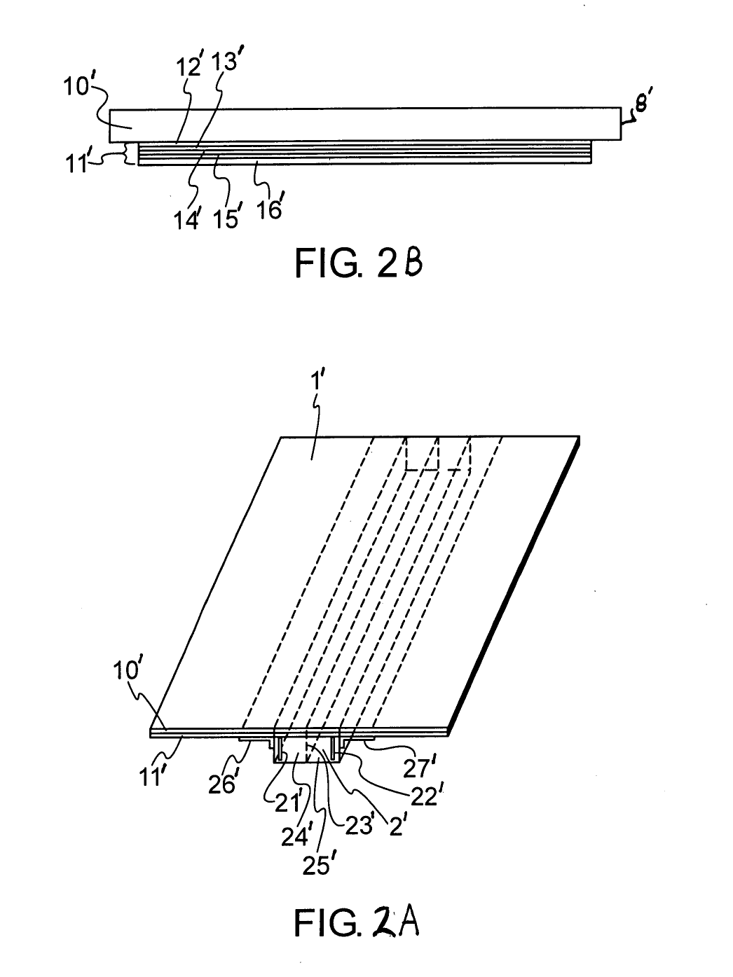

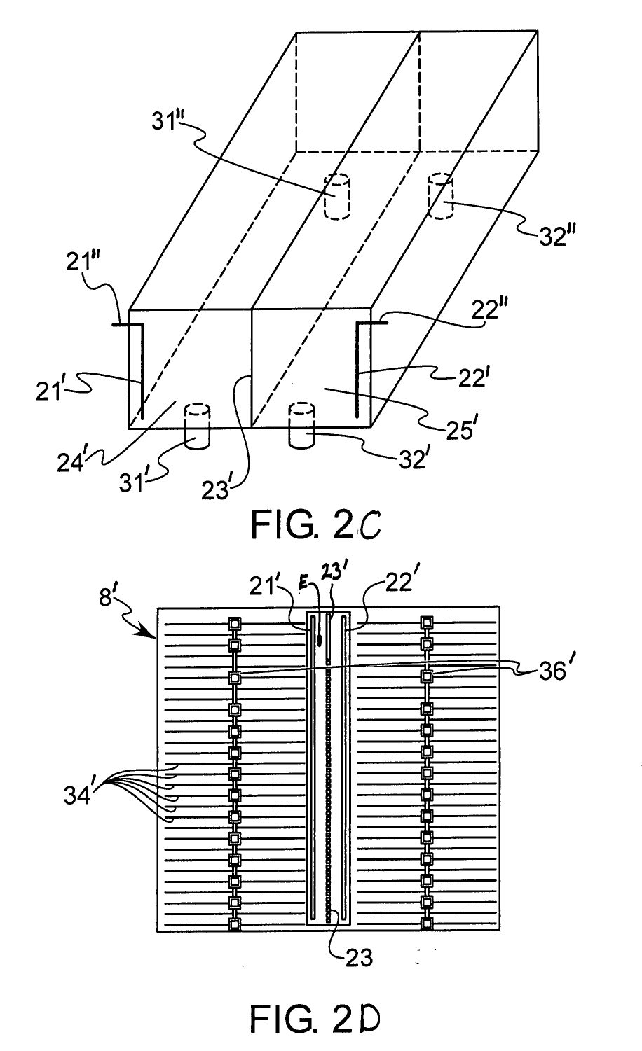

Referring now to FIG. 2a, the integrated photovoltaic electrolysis (IPE) cell comprises a photovoltaic component 1′ and an electrolysis component 2′.

The superstrate photovoltaic cell 8′ has a superstrate 10′ and photovoltaic layers 11′, such as p-i-n junctions composed of semiconducting layers of hydrogenated amorphous silicon, amorphous germanium or their alloys, transparent conducting layers of zinc oxide and/or indium-tin oxide, and metallic reflector layers of silver or aluminum. However, in the embodiments shown in FIG. 2a, the photovoltaic layers 10′ are deposited on the superstrate 10, which, for example, can be glass or another transparent material. The light enters through the superstrate 10′ of photovoltaic cell 8′. In certain embodiments, the photovoltaic component 1′ is subdivided into a multiple of subcells, with appropriate dimensions such that the electrical loss in the transparent and conducting front contact is minimal since scribes 34, as shown in FIG. 2d, (such as laser scribe, chemical scribe or mechanical scribe) are connected to current collection bus bars 36.

In certain embodiments, where a photovoltaic structure does not produce sufficient voltage to drive water electrolysis, two or more subcells can be connected, through appropriate scribes, into a photovoltaic unit cell which has sufficient voltage to drive water electrolysis at or near its maximum power point.

In other embodiments, where a photovoltaic structure does produce sufficient voltage to drive water electrolysis at or near its maximum power point (for example, a triple-junction amorphous silicon structure), each subcell is a photovoltaic unit cell. An additional scribe is made to bring the positive electrode of the photovoltaic unit cell from the transparent conducting front contact to an electrically isolated contact on the back contact, without shorting the positive and negative electrodes, and with minimized photovoltaic dead area; such as, for example, dead areas used for the purposed of interconnections.

The subcells within a photovoltaic unit cell have approximately equal active area so that the photocurrent generated in each subcell within the unit cell is approximately the same. The subcells and unit cells are positioned in such a way that, during operation, the longer sides are placed horizontally or approximately horizontally.

As best seen in FIG. 2c, the electrolysis 2′ component includes an electrical connections 21″ for the cathode 21′, an electrical connections 22″ for the anode 22′, a separator membrane 23′, an inlet 31′ for the electrolyte, an outlet 31″ for the electrolyte and hydrogen; an inlet 32′ for electrolyte, and an outlet 32″ for electrolyte and oxygen.

On a first side of the photovoltaic component 1′, the negative electrodes of some or all photovoltaic unit cells are electrically connected together to the negative contact, which is electrically connected to the cathode of the electrolysis component.

On a second other side of the photovoltaic component 1′, the positive electrodes of some or all photovoltaic unit cells are electrically connected together to a positive contact, which is electrically connected to the anode of the electrolysis component.

The electrolysis component 2′ is positioned at, or near, the back of the photovoltaic component 1′ in such an orientation that the reduction compartment 24′ is on, or close to, the first side; and, the oxidation compartment 25′ is on, or close to, the second side for low-loss electrical connections.

The foregoing has outlined in broad terms the more important features of the invention disclosed herein so that the detailed description that follows may be more clearly understood, and so that the contribution of the instant inventor to the art may be better appreciated. The instant invention is not to be limited in its appreciation to the details of the construction and to the arrangements of the components set forth in the following description or illustrated in the drawings. Rather, the invention is capable of other embodiments and of being practiced and carried out in various other ways not specifically enumerated herein. Finally, it should be understood that the phraseology and terminology employed herein are for the purpose of description and should not be regarded as limiting, unless the specification specifically so limits the invention.

### EXAMPLE 1

### Substrate Type

A triple-junction amorphous silicon photovoltaic cell was used as the photovoltaic component of an integrated photovoltaic electrochemical (IPE) cell of the substrate type.

The cell had amorphous silicon and silicon-germanium semiconducting layers on a stainless steel substrate coated with aluminum and zinc-oxide. An ITO top contact and metal grids were used to collect the current from the front surface of the photovoltaic cell. The back of the photovoltaic cell was bonded to one surface of a metallic plate of the same size. The other side of the plate served as the cathode of the electrolysis component. The metal chosen was a good catalyst for the evolution of hydrogen. The front contact of the photovoltaic cell was connected to a second metal electrode which was a suitable catalyst for oxygen evolution. The electrolyte used was a 30% aqueous solution of potassium hydroxide (KOH).

The area of the photovoltaic cell was 107.6 square centimeters and the amount of irradiation was 0.88 suns or 88 mW/cm². The IPE cell produced hydrogen at a rate of 2.28 ml/minute, which corresponds to a gross solar-to-hydrogen conversion efficiency of 4.2%.

### EXAMPLE 1A

The photovoltaic component is a substrate-type thin-film silicon based solar cell deposited on a stainless substrate, comprises: a stainless steel substrate; a reflective and textured metal layer deposited on the stainless steel substrate; optionally, a transparent conducting oxide layer serving as a buffer layer; two or more of photovoltaic junction(s) which is comprised of an optically transparent and electrically conductive front contact such as indium oxide, tin oxide, zinc oxide, or a combination or alloys of these oxide materials.

In certain embodiments, each of the photovoltaic junction(s) is comprised of: an undoped or lightly doped hydrogenated semiconductor material based on amorphous silicon, microcrystalline silicon, nanocrystalline silicon, amorphous germanium, microcrystalline germanium, nanocrystalline germanium, or alloys of two or more of these materials, having bandgap (or bandgaps) appropriately selected, by adjusting, for example, the content of germanium or hydrogen in hydrogenated amorphous silicon germanium alloy (a-Si1-xGex:H), so that the photovoltaic component and electrolysis component are load matched; a p-type Si-based semiconductor material; and, an n-type Si-based semiconductor.

### EXAMPLE 2

### Superstrate Type

An amorphous silicon-amorphous silicon tandem panel deposited on a glass substrate was used as the photovoltaic component in an integrated photovoltaic electrochemical (IPE) cell of the superstrate type. The a-Si-a-Si tandem cell produces an open circuit voltage of approximately 1.5 V, which is somewhat insufficient for electrolysis. Hence, the panel was divided into two-cell pairs, each pair producing an open circuit voltage of approximately 3 V, which is sufficient for electrolysis.

The anodes and cathodes of the cell pairs were connected together to produce a single cell. This cell had an open circuit voltage of ˜3V. This cell was connected to an electrolyzer box, the length of which was the same as the length of the photovoltaic panel. The electrolyzer incorporated electrodes with hydrogen and oxygen evolution catalysts, as well as a membrane to keep the evolved gases separate. The electrolyte used was a 30% aqueous solution of potassium hydroxide (KOH).

The area of the photovoltaic cell was 855 square centimeters and the amount of irradiation was 1 sun or 100 mW/cm². The IPE cell produced hydrogen at a rate of 10.1 ml/minute, which corresponds to a gross solar-to-hydrogen conversion efficiency of 2.1%.

### EXAMPLE 2A

The photovoltaic component is a superstrate-type thin-film silicon based solar cell deposited on a glass superstrate, comprising: a glass superstrate; a transparent conducting oxide deposited on the glass superstrate; one or more of photovoltaic junction(s); and, an optically reflective and electrically conductive back contact. In certain embodiments, each of the photovoltaic junction(s) is comprised of: an undoped or lightly doped hydrogenated semiconductor material based on amorphous silicon, microcrystalline silicon, nanocrystalline silicon, amorphous germanium, microcrystalline germanium, nanocrystalline germanium, or alloys of two or more of these materials, having bandgap (or bandgaps) appropriately selected, by adjusting, for example, the content of germanium or hydrogen in hydrogenated amorphous silicon germanium alloy (a-Si1-xGex:H), so that the photovoltaic component and electrolysis component are load matched; a p-type Si-based semiconductor material; and, an n-type Si-based semiconductor

### EXAMPLE 3

An integrated photovoltaic electrolysis (IPE) cell includes a photovoltaic component and an electrolysis component which are integrated, through an interconnect design, into a single unit.

The photovoltaic component, a, is comprised of:

a1: a superstrate or a substrate;

a2: a transparent conducting front electrode;

a3: one or more of photovoltaic junction(s); and.

a4: an electrically conductive back electrode.

The electrolysis component is comprised of:

b1: an electrolyte;

b2: an enclosure that confines the electrolyte;

b3: a reduction compartment for hydrogen generation;

b4: an oxidation compartment for oxygen generation;

b6: a cathode that is electrically connected to the negative electrode of the photovoltaic component; such cathode is either made of or coated with a stable hydrogen generation catalyst material that has low hydrogen evolution overpotential and is electrochemically stable under reduction environment;

b7: an anode that is electrically connected to the positive electrode of the photovoltaic component; such anode is either made of or coated with a stable oxygen generation catalyst material that has low oxygen evolution overpotential and is electrochemically stable under oxidation environment;

b10: an electrolyte inlet for each or both of the reduction and oxidation compartments;

b11: an outlet for electrolyte and hydrogen in the reduction compartment; and,

b12: an outlet for electrolyte and oxygen in the oxidation compartment.

### EXAMPLE 4

The integrated photovoltaic electrolysis (IPE) cell has a photovoltaic component which is a superstrate-type thin-film photovoltaic cell deposited on a glass superstrate; and, a water electrolysis component is used.

In certain embodiments, the interconnect design is comprised of one or more of the following aspects:

c1: the photovoltaic component is subdivided into a multiple of subcells, with appropriate dimensions such that the electrical loss in the transparent and conducting front contact is minimal, using scribes such as laser scribe, chemical scribe or mechanical scribe.

Further, in certain embodiments,

c2: for a photovoltaic structure that does not produce sufficient voltage to drive water electrolysis, two or more subcells are connected, through appropriate scribes, into a photovoltaic unit cell which has sufficient voltage to drive water electrolysis at or near its maximum power point.

For a photovoltaic structure that does produce sufficient voltage to drive water electrolysis at or near its maximum power point, each subcell is a photovoltaic unit cell.

Also, in certain embodiments,

c3: an additional scribe is made to bring the positive electrode of the photovoltaic unit cell from the transparent conducting front contact to an electrically isolated contact on the back contact, without shorting the positive and negative electrodes, and with minimized photovoltaic dead areas.

### EXAMPLE 5

An integrated photovoltaic electrolysis (IPE) cell has a photovoltaic component which is a substrate-type thin-film photovoltaic cell, deposited on a conducting substrate, and has one or more photovoltaic junctions, so that the photovoltage is sufficient to drive water electrolysis.

In certain embodiments,

c. the interconnect design is comprised of one or more of the following aspects:

c1: electrical grids are applied on top of the transparent conducting front electrode; and the spacing of the grids is such that the electrical loss in the transparent and conducting front electrode is minimal;

c2: these electrical grids are electrically connected together and to one electrode of the electrolysis component; and/or,

c3: the conducting substrate is electrically connected to the other electrode of the electrolysis component, or itself is the other electrode.

### EXAMPLE 6

The integrated photovoltaic electrolysis (IPE) cell has an electrolysis component comprised of:

b1: an alkaline electrolyte with approximately 30% KOH;

b5: a membrane that keeps hydrogen and oxygen separated while allowing ions to conduct through; and,

b8: an electrode spacing between the anode and cathode of approximately 2-3 cm;

In certain embodiments, the electrolysis component has a compact design:

b9.1: with a length, which is slightly larger than the length of the electrodes, being approximately the same as the length (or width) of the photovoltaic component;

b9.2: with a width, which is slightly larger than the spacing between the cathode and anode, being substantially smaller than the width (or length) of the photovoltaic component; and,

b9.3: with a width, which is slightly larger than the width of the electrodes.

Also, in certain embodiments, the width is determined using one or more of the following criteria:

b9.3.1: the current density on the cathode, during operation under sunlight, is sufficiently small, consequently the overpotential for hydrogen generation is sufficiently small, so that the overall operating voltage of the electrolysis component can be minimized;

b9.3.2: the current density on the anode, during operation under sunlight, is sufficiently small, consequently the overpotential for oxygen generation is sufficiently small, so that the overall operating voltage of the electrolysis component can be minimized;

b9.3.3 the material usage of for the electrodes and catalyst materials are minimized; and/or,

b9.3.4 the thickness of the electrolysis component is minimal for low materials and fabrication costs and for broader device applications.

### EXAMPLE 7

The IPE cell further includes one or more of the following:

b10: an electrolyte inlet for each of the reduction and oxidation compartments, at or near one end (the lower end) of the electrolysis component; optionally, the two inlets may be combined;

b11: an outlet for electrolyte and hydrogen placed at the upper end of the reduction compartment; and/or,

b12: an outlet for electrolyte and oxygen placed at the upper end of the oxidation compartment.

### EXAMPLE 8

An integrated photovoltaic electrolysis (IPE) cell has a photovoltaic component which is a superstrate-type thin-film silicon based photovoltaic cell deposited on a glass superstrate, comprising

a1: a glass superstrate,

a2: a transparent conducting oxide deposited on the glass superstrate,

a3: one or more of photovoltaic junction(s) which is comprised of:

a3.1: an undoped or lightly doped hydrogenated semiconductor material based on amorphous silicon, microcrystalline silicon, nanocrystalline silicon, amorphous germanium, microcrystalline germanium, nanocrystalline germanium, or alloys of two or more of these materials, having bandgap (or bandgaps) appropriately selected, by adjusting, for example, the content of germanium or hydrogen in hydrogenated amorphous silicon germanium alloy (a-Si₁₋ₓGeₓ:H), so that the photovoltaic component and electrolysis component are load matched;

a3.2 a p-type Si-based semiconductor material;

a3.3 an n-type Si-based semiconductor; and,

a4: an optically reflective and electrically conductive back contact.

### EXAMPLE 9

An integrated photovoltaic electrolysis (IPE) cell has a photovoltaic component which is a substrate-type thin-film silicon based photovoltaic cell deposited on a metallic substrate, comprising one or more of the following:

a1: a metallic substrate sheet;

a2: a reflective and textured metal layer deposited on the metallic substrate; and/or,

a3: optionally, a transparent conducting oxide layer serving as a buffer layer.

In certain embodiments, two or more of photovoltaic junction(s) are comprised of

a3.1: an undoped or lightly doped hydrogenated semiconductor material based on amorphous silicon, microcrystalline silicon, nanocrystalline silicon, amorphous germanium, microcrystalline germanium, nanocrystalline germanium, or alloys of two or more of these materials, having bandgap (or bandgaps) appropriately selected, by adjusting, for example, the content of germanium or hydrogen in hydrogenated amorphous silicon germanium alloy (a-Si₁₋ₓGeₓ:H), so that the photovoltaic component and electrolysis component are load matched;

a3.2 a p-type Si-based semiconductor material;

a3.3 an n-type Si-based semiconductor; and,

a5: an optically transparent and electrically conductive front contact such as indium oxide, tin oxide, zinc oxide, or a combination or alloys of these oxide materials.

### EXAMPLE 10

In certain embodiments, the integrated photovoltaic electrolysis (IPE) cell includes one or more of the following:

a1. the metallic substrate which comprises stainless steel; and/or,

a2: the metallic substrate which is coated with, or bonded to, a catalyst material.

In certain embodiments, one or more of the following criteria are met: the substrate is coated with, or bonded to, a catalyst material; the substrate for the photovoltaic component is itself a catalyst; the catalyst material comprises a nickel material; the substrate material comprises a nickel material.

The integrated photovoltaic electrolysis cell of claim 1, wherein the electrode material is nickel-based catalyst or porous nickel-based catalyst.

### EXAMPLE 11

In certain embodiments, in the integrated photovoltaic electrolysis (IPE) cell the metallic substrate for the photovoltaic component is itself a catalyst material is nickel.

In other embodiments, the substrate material is nickel.

In still other embodiments, the electrode material is nickel-based catalyst or porous nickel-based catalyst.

### EXAMPLE 12

A method for forming an integrated photovoltaic electrolysis (IPE) cell includes a integrating photovoltaic component and an electrolysis component, through an interconnect design, into a single unit. The photovoltaic component is comprised of one or more of the superstrate or substrate components as described herein.

In certain embodiments, the photovoltaic component is a superstrate-type thin-film photovoltaic cell deposited on a glass superstrate; the electrolysis component is water; and the photovoltaic component is subdivided into a multiple of subcells; with appropriate dimensions such that the electrical loss in the transparent and conducting front contact is minimal.

In other embodiments, the photovoltaic component is a substrate-type thin-film photovoltaic cell, deposited on a conducting substrate, having one or more photovoltaic junctions, so that the photovoltage is sufficient to drive water electrolysis. The electrical grids are applied on top of the transparent conducting front electrode; wherein spacing of the grids is such that the electrical loss in the transparent and conducting front electrode is minimal. The electrical grids are electrically connected together and to one electrode of the electrolysis component. The conducting substrate is electrically connected to the other electrode of the electrolysis component, or itself is the other electrode.

The above descriptions of the preferred and alternative embodiments of the present invention are intended to be illustrative and are not intended to be limiting upon the scope and content of the following claims.

All of the compositions and methods disclosed and claimed herein can be made and executed without undue experimentation in light of the present disclosure. While the compositions and methods of this invention have been described in terms of the foregoing illustrative embodiments, it will be apparent to those skilled in the art that variations, changes, modifications, and alterations may be applied to the compositions and/or methods described herein, without departing from the true concept, spirit, and scope of the invention. More specifically, it will be apparent that certain agents that are both chemically and physiologically related may be substituted for the agents described herein while the same or similar results would be achieved. All such similar substitutes and modifications apparent to those skilled in the art are deemed to be within the spirit, scope, and concept of the invention as defined by the appended claims.

In accordance with the provisions of the patent statutes, the principle and mode of operation of this invention have been explained and illustrated in its preferred embodiment. However, it must be understood that this invention may be practiced otherwise than as specifically explained and illustrated without departing from its spirit or scope.

The references disclosed herein, to the extent that they provide exemplary procedural or other details supplementary to those set forth herein, are specifically incorporated herein by reference.

What is claimed is:

1. An integrated photovoltaic electrolysis (IPE) cell, comprising a photovoltaic component and an electrolysis component integrated, through an interconnect design, into a single unit,
wherein the photovoltaic component is comprised of:
a superstrate or a substrate;
a transparent conducting front electrode;
one or more of photovoltaic junction(s); and,
an electrically conductive back electrode;
and wherein the electrolysis component is comprised of:
an electrolyte;
an enclosure that confines the electrolyte;
a reduction compartment for hydrogen generation;
an oxidation compartment for oxygen generation;
a cathode that is electrically connected to the negative electrode of the photovoltaic component; such cathode is either made of or coated with a stable hydrogen generation catalyst material that has low hydrogen evolution overpotential and is electrochemically stable under reduction environment;
an anode that is electrically connected to the positive electrode of the photovoltaic component; such anode is either made of or coated with a stable oxygen generation catalyst material that has low oxygen evolution overpotential and is electrochemically stable under oxidation environment;
an electrolyte inlet for each or both of the reduction and oxidation compartments;
an outlet for electrolyte and hydrogen in the reduction compartment; and,
an outlet for electrolyte and oxygen in the oxidation compartment.

2. The integrated photovoltaic electrolysis cell of claim 1, wherein the photovoltaic component is a superstrate-type thin-film photovoltaic cell deposited on a glass superstrate.

3. The integrated photovoltaic electrolysis cell of claim 2, wherein the photovoltaic component is subdivided into a multiple of subcells; with appropriate dimensions such that the electrical loss in the transparent and conducting front contact is minimal;
an additional scribe is made to bring the positive electrode of the photovoltaic unit cell from the transparent conducting front contact to an electrically isolated contact on a back contact, without shorting the positive and negative electrodes, and with minimized photovoltaic dead area;
the subcells within the photovoltaic unit cell have approximately equal active areas so that a photocurrent generated in each subcell within the unit cell is approximately the same;
a first side of the photovoltaic component, the negative electrodes of some or all photovoltaic unit cells are electrically connected together to a negative contact, which is electrically connected to the cathode of the electrolysis component; and,
on a second side of the photovoltaic component, the positive electrodes of some or all photovoltaic unit cells are electrically connected together to a positive contact, which is electrically connected to the anode of the electrolysis component;
wherein the electrolysis component is positioned at or near the back of the photovoltaic component in such an orientation that its reduction compartment is on, or close to, the first side; and the oxidation compartment is on, or close to, the second side for low-loss electrical connections.

4. The integrated photovoltaic electrolysis cell of claim 3, wherein two or more subcells are connected, through appropriate scribes, into a photovoltaic unit cell which has sufficient voltage to drive water electrolysis at or near its maximum power point.

5. The integrated photovoltaic electrolysis cell of claim 3, wherein each subcell is a photovoltaic unit cell.

6. The integrated photovoltaic electrolysis cell of claim 3, wherein the electrolysis component is comprised of:
an alkaline electrolyte;
a membrane that keeps hydrogen and oxygen separated while allowing ions to conduct through;
an electrode spacing between the anode and cathode;
wherein the electrolysis component includes:
an electrolyte inlet for each of the reduction and oxidation compartments, at or near one end (the lower end) of the electrolysis component;
an outlet for electrolyte and hydrogen placed at the upper end of the reduction compartment; and,
an outlet for electrolyte and oxygen placed at the upper end of the oxidation compartment.

7. The integrated photovoltaic electrolysis cell of claim 6, wherein the electrolysis component has a compact design:
with a length, which is slightly larger than the length of the electrodes, being approximately the same as the length (or width) of the photovoltaic component;
with a width, which is slightly larger than the spacing between the cathode and anode, being substantially smaller than the width (or length) of the photovoltaic component; and,
with a thickness, which is slightly larger than the width of the electrodes.

8. The integrated photovoltaic electrolysis cell of claim 7, wherein the width is determined using one or more of the following criteria:
the current density on the cathode, during operation under sunlight, is sufficiently small, consequently the overpotential for hydrogen generation is sufficiently small, so that the overall operating voltage of the electrolysis component can be minimized; and/or
the current density on the anode, during operation under sunlight, is sufficiently small, consequently the overpotential for oxygen generation is sufficiently small, so that the overall operating voltage of the electrolysis component can be minimized.

9. The integrated photovoltaic electrolysis cell of claim 6, wherein the two inlets are combined.

10. The integrated photovoltaic electrolysis cell of claim 2, wherein the photovoltaic component is a superstrate-type thin-film silicon based solar cell deposited on a superstrate, comprising
a superstrate;
a transparent conducting oxide deposited on the superstrate;
one or more of photovoltaic junctions; and,
an optically reflective and electrically conductive back contact.

11. The integrated photovoltaic electrolysis cell of claim 10, wherein each of the photovoltaic junction(s) is comprised of
an undoped or lightly doped hydrogenated semiconductor material based on amorphous silicon, microcrystalline silicon, nanocrystalline silicon, amorphous germanium, microcrystalline germanium, nanocrystalline germanium, or alloys of two or more of these materials;
a p-type Si-based semiconductor material; and,
an n-type Si-based semiconductor.

12. The integrated photovoltaic electrolysis cell of claim 1, wherein the photovoltaic component is a substrate-type thin-film photovoltaic cell, deposited on a conducting substrate, having one or more photovoltaic junctions, so that the photovoltage is sufficient to drive water electrolysis.

13. The integrated photovoltaic electrolysis cell of claim 12, wherein the substrate-type thin film photovoltaic cell comprises:
electrical grids applied on top of the transparent conducting front electrode; wherein spacing of the grids is such that the electrical loss in the transparent and conducting front electrode is minimal;
the electrical grids are electrically connected together and to one electrode of the electrolysis component; and,
the conducting substrate is electrically connected to the other electrode of the electrolysis component, or itself is the other electrode.

14. The integrated photovoltaic electrolysis cell of claim 12, wherein the electrolysis component is comprised of:
an alkaline electrolyte;
a membrane that keeps hydrogen and oxygen separated while allowing ions to conduct through; and,
an electrode spacing between the anode and cathode;
wherein the electrolysis component includes:
an electrolyte inlet for each of the reduction and oxidation compartments, at or near one end (the lower end) of the electrolysis component;
an outlet for electrolyte and hydrogen placed at the upper end of the reduction compartment; and,
an outlet for electrolyte and oxygen placed at the upper end of the oxidation compartment.

15. The integrated photovoltaic electrolysis cell of claim 14, wherein the electrolysis component has a compact design with the following aspects:
with a length, which is slightly larger than the length of the electrodes, being approximately the same as the length (or width) of the photovoltaic component;
with a width, which is slightly larger than the spacing between the cathode and anode, being substantially smaller than the width (or length) of the photovoltaic component; and,
with a thickness, which is slightly larger than the width of the electrodes.

16. The integrated photovoltaic electrolysis cell of claim 15, wherein the width of the electrode is determined using one or more of the following criteria:
the current density on the cathode, during operation under sunlight, is sufficiently small, consequently the overpotential for hydrogen generation is sufficiently small, so that the overall operating voltage of the electrolysis component can be minimized; and/or,
the current density on the anode, during operation under sunlight, is sufficiently small, consequently the overpotential for oxygen generation is sufficiently small, so that the overall operating voltage of the electrolysis component can be minimized.

17. The integrated photovoltaic electrolysis cell of claim 16, wherein the two inlets are combined.

18. The integrated photovoltaic electrolysis cell of claim 12, wherein the photovoltaic component is a substrate-type thin-film silicon based solar cell deposited on a stainless substrate, comprising:
a stainless steel substrate;
a reflective and textured metal layer deposited on the stainless steel substrate;
one or more of photovoltaic junction(s) which is comprised of: an optically transparent and electrically conductive front contact.

19. The integrated photovoltaic electrolysis cell of claim 18, further including a transparent conducting oxide layer serving as a buffer layer.

20. The integrated photovoltaic electrolysis cell of claim 18, wherein each of the photovoltaic junction(s) is comprised of
an undoped or lightly doped hydrogenated semiconductor material based on amorphous silicon, microcrystalline silicon, nanocrystalline silicon, amorphous germanium, microcrystalline germanium, nanocrystalline germanium, or alloys of two or more of these materials; a p-type Si-based semiconductor material; and, an n-type Si-based semiconductor.

21. The integrated photovoltaic electrolysis cell of claim 1, wherein the substrate is coated with, or bonded to, a catalyst material.

22. The integrated photovoltaic electrolysis cell of claim 1, wherein the substrate for the photovoltaic component is itself a catalyst.

23. The integrated photovoltaic electrolysis cell of claim 1, wherein the catalyst material comprises a nickel material.

24. The integrated photovoltaic electrolysis cell of claim 1, wherein the substrate material comprises a nickel material.

25. The integrated photovoltaic electrolysis cell of claim 1, wherein the electrode material is nickel-based catalyst or porous nickel-based catalyst.
